(19) United States
(12) Patent Application Publication
(10) Pub. No.: US 2026/0293010 A1
(43) Pub. Date: Sep. 24, 2026

(54) DISPLAY APPARATUS AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Jianpeng ZHAI, Beijing (CN); Jiafan SHI, Beijing (CN); Liqiang CHEN, Beijing (CN); Chao YANG, Beijing (CN)

(21) Appl. No.: 19/479,284

(22) PCT Filed: Sep. 13, 2024
(86) PCT No.: PCT/CN2024/118713

§ 371 Date: Oct. 27, 2025

(30) Foreign Application Priority Data
Oct. 30, 2023 (CN) 202311423716.8

(51) Int. Cl. H05K 5/02; H05K 5/03; H10K 59/12; H10K 59/80

(52) U.S. Cl. CPC H05K 5/0247; H05K 5/0217; H05K 5/03; H10K 59/1201; H10K 59/873; H10K 59/8792

(57) ABSTRACT

Provided is a display device. The display device includes a display panel, a cover plate, and a grounding member. The cover plate is disposed on a light-emitting surface of the display panel, the grounding member is disposed on a backlight surface of the display panel, and the protective frame is disposed around the display panel and connected to an edge of the cover plate. The protective frame includes an insulating body and a conductive structure embedded in the insulating body, the conductive structure being connected to the edge of the cover plate and connected to the grounding member.

The present disclosure is a U.S. national stage of international application No. PCT/CN2024/118713, which claims priority to Chinese Patent Application No. 202311423716.8, filed on Oct. 30, 2023, and entitled “DISPLAY DEVICE, METHOD FOR MANUFACTURING SAME, AND DISPLAY APPARATUS”, the disclosure of which is herein incorporated by reference in its entirety.

### TECHNICAL FIELD

The present disclosure relates to the technical field of display devices, and in particular, relates to a display device, a method for manufacturing the same, and a display apparatus.

### BACKGROUND

With the rapid development of the display industry, display devices are widely used in people's daily lives, such as in mobile phones, monitors, and tablet computers.

### SUMMARY

Embodiments of the present disclosure provide a display device, a method for manufacturing the same, and a display apparatus. The technical solutions are as follows.

A display device is provided. The display device includes a display panel, a cover plate, a grounding member, and a protective frame. The cover plate is disposed on a light-emitting surface of the display panel; the grounding member is disposed on a backlight surface of the display panel; the protective frame is disposed around the display panel and connected to an edge of the cover plate, the protective frame includes an insulating body and a conductive structure embedded in the insulating body, and the conductive structure is connected to the edge of the cover plate and electrically connected to the grounding member.

In some embodiments, the conductive structure includes at least one connector, the connector includes a first connection structure and a second connection structure, an end of the second connection structure is connected to the first connection structure, and a side surface of the first connection structure is attached to the edge of the cover plate.

In some embodiments, the conductive structure further includes a third connection structure, and the third connection structure is connected to an end of the second connection structure distal to the first connection structure, and is connected to the grounding member.

In some embodiments, the grounding member is attached to the backlight surface of the display panel, and a side surface of the third connection structure is attached to a surface of the grounding member distal to the display panel.

In some embodiments, the third connection structure is a snap-fit, a bolt, or a nut.

In some embodiments, the conductive structure includes a plurality of connectors, and the multiple connectors are arranged spaced apart from each other around the display panel.

In some embodiments, the conductive structure contains multiple conductive particles, and the multiple conductive particles are evenly distributed in the insulating body.

In some embodiments, the grounding member includes at least one of a metal support layer, an integral middle frame, or a copper foil in a super clean foam layer.

In some embodiments, the display panel includes a back film layer and a display layer, the display layer includes a light-emitting surface and a backlight surface opposite to each other, the light-emitting surface of the display layer faces the same direction as the light-emitting surface of the display panel, the backlight surface of the display layer faces the same direction as the backlight surface of the display panel, and the back film layer is disposed on the backlight surface of the display layer.

In some embodiments, the display device further includes a light-shielding structure. The light-shielding structure is disposed on a surface of the cover plate proximal to the display panel and disposed at the edge of the cover plate, and the light-shielding structure is conductive and connected to the conductive structure.

In some embodiments, the insulating body is manufactured by using an in-mold injection molding process or a 3D printing process.

A method for manufacturing a display device is provided. The method includes: connecting a cover plate to a display panel, wherein the cover plate is disposed on a light-emitting surface of the display panel; forming a grounding member on a backlight surface of the display panel; and forming a protective frame around the display panel, wherein the protective frame is connected to an edge of the cover plate, the protective frame includes an insulating body and a conductive structure embedded in the insulating body, and the conductive structure is connected to the edge of the cover plate and electrically connected to the grounding member.

In some embodiments, forming the protective frame includes: forming at least one connector around the display panel, wherein the connector includes a first connection structure and a second connection structure, an end of the second connection structure is connected to the first connection structure, and a side surface of the first connection structure is attached to the edge of the cover plate; and forming the insulating body by using an in-mold injection molding process or a 3D printing process to obtain the protective frame.

In some embodiments, forming the protective frame includes: incorporating a plurality of conductive particles into an insulating material, such that the multiple conductive particles are evenly distributed in the insulating material; and forming the protective frame based on the insulating material by using an in-mold injection molding process or a 3D printing process.

A display apparatus is provided. The display apparatus includes the display device described above and a power supply, and the display device is electrically connected to the power supply.

### BRIEF DESCRIPTION OF DRAWINGS

For a clearer illustration of the technical solutions in the embodiments of the present disclosure, the accompanying drawings required to be used in the description of the embodiments are briefly introduced hereinafter. It is apparent that the accompanying drawings in the description hereinafter are only for some embodiments of the present disclosure, and for those of ordinary skill in the art, other accompanying drawings can be acquired according to the accompanying drawings without creative efforts.

FIG. 1 is a schematic structural diagram of a display device in the related art;

FIG. 2 is a schematic diagram of the edge greening phenomenon of a display device in the related art;

FIG. 3 is a schematic structural diagram of a display device according to some embodiments of the present disclosure;

FIG. 4 is a schematic structural diagram of another display device according to some embodiments of the present disclosure;

FIG. 5 is a schematic structural diagram of yet another display device according to some embodiments of the present disclosure;

FIG. 6 is a schematic structural diagram of yet another display device according to some embodiments of the present disclosure;

FIG. 7 is a schematic structural diagram of yet another display device according to some embodiments of the present disclosure;

FIG. 8 is a flowchart of a method for manufacturing a display device according to some embodiments of the present disclosure;

FIG. 9 is a flowchart of another method for manufacturing a display device according to some embodiments of the present disclosure;

FIG. 10 is a schematic structural diagram of a display device during manufacturing according to some embodiments of the present disclosure;

FIG. 11 is a schematic structural diagram of another display device during manufacturing according to some embodiments of the present disclosure;

FIG. 12 is a flowchart of yet another method for manufacturing a display device according to some embodiments of the present disclosure; and

FIG. 13 is a schematic structural diagram of a display apparatus according to some embodiments of the present disclosure.

### DETAILED DESCRIPTION

For clearer descriptions of the objectives, technical solutions, and advantages of the present disclosure, embodiments of the present disclosure are further described in detail hereinafter with reference to the accompanying drawings.

Unless otherwise defined, technical or scientific terms used herein shall have the ordinary meaning as understood by those of ordinary skill in the art to which the present disclosure belongs. The terms “first”, “second”, “third”, and other similar words, as used in the specification and in the claims of the patent application of the present disclosure, do not indicate any order, quantity, or importance, but are merely defined to distinguish different components. Likewise, the terms “a”, “an”, or other similar words do not indicate a limitation of quantity, but rather the presence of at least one. The terms “include”, “comprise”, or other similar words indicate that the elements or objects stated before “include” or “comprise” encompass the elements or objects and equivalents thereof listed after “include” or “comprise”, but do not exclude other elements or objects. The terms “connecting”, “connected”, or other similar words are not limited to physical or mechanical connections, but may include electrical connections, whether direct or indirect. “Upper”, “lower”, “left”, “right”, “top”, “bottom”, and the like are only used to indicate relative positional relationships. In the case that the absolute position of the described object changes, the relative positional relationships may also change accordingly. In addition, in the specification and claims, “and/or” indicates at least one of connected objects, and the character “/” generally indicates an “or” relationship between the associated objects before and after the “/”.

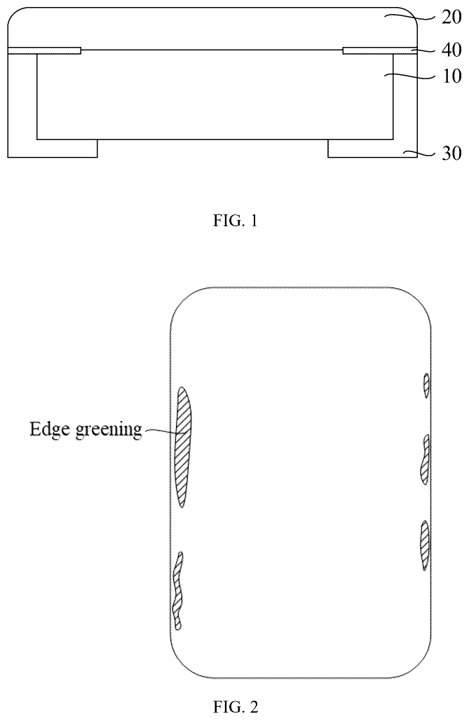

FIG. 1 is a schematic structural diagram of a display device in the related art. As shown in FIG. 1, the display device includes a display panel 10, a cover plate 20, a protective frame 30, and a light-shielding structure 40. The cover plate 20 is disposed on a light-emitting surface of the display panel 10, the protective frame 30 is disposed around the display panel 10 and connected to an edge of the cover plate 20, and the light-shielding structure 40 is disposed on the surface of the cover plate 20 proximal to the display panel 10 and at the edge of the cover plate 20.

In the case that static charges are generated on the cover plate 20, since the protective frame 30 connected to the cover plate 20 is generally made of an insulating material, it cannot effectively dissipate the static charges on the surface of the cover plate 20. In electro-static discharge (ESD)-related tests, such as copper rod friction and an electrostatic field, the display device shows problems such as edge greening, resulting in a low yield of display devices.

FIG. 2 is a schematic diagram of the edge greening phenomenon of a display device in the related art. As shown in FIG. 2, after the ESD test is performed on the display device in the related art, the static charges, as they cannot be effectively dissipated, accumulate at the edge portion of the display device, such that the display effect of the display device is affected, and the edge portion of the display device shows the problem of greening.

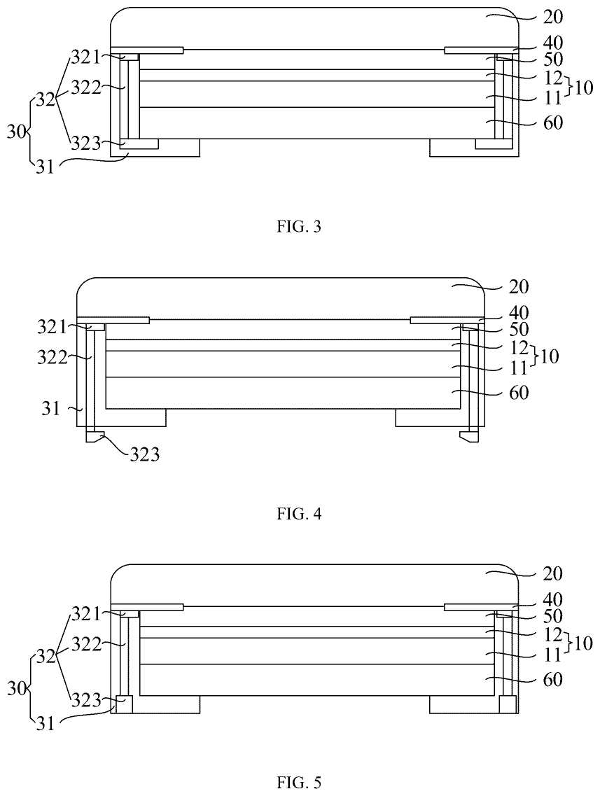

FIG. 3 is a schematic structural diagram of a display device according to some embodiments of the present disclosure. As shown in FIG. 3, the display device includes a display panel 10, a cover plate 20, a grounding member, and a protective frame 30. The cover plate 20 is disposed on a light-emitting surface of the display panel 10; the grounding member is disposed on a backlight surface of the display panel 10; the protective frame 30 is disposed around the display panel 10 and connected to an edge of the cover plate 20, the protective frame 30 includes an insulating body 31 and a conductive structure 32, the conductive structure 32 is embedded in the insulating body 31, and the conductive structure 32 is connected to the edge of the cover plate 20 and electrically connected to the grounding member.

In the embodiments of the present disclosure, the grounding member is disposed on the backlight surface of the display panel 10, the protective frame 30 is disposed around the display panel 10 and connected to the edge of the cover plate 20, the protective frame 30 includes an insulating body 31 and a conductive structure 32, the conductive structure 32 is embedded in the insulating body 31, and the conductive structure 32 is connected to the edge of the cover plate 20 and electrically connected to the grounding member. In the case that static charges are generated on the cover plate 20, the conductive structure 32 in the protective frame 30 transmit the static charges to the grounding member for grounding, which facilitates the diffusion of the static charges and reduces problems such as edge greening caused by the accumulation of the static charges at the edge of the cover plate 20, thereby improving the yield of display devices.

In some embodiments, the cover plate 20 is a transparent cover plate, such as a cover glass (CG) or a plastic plate.

In some embodiments, the insulating body 31 is manufactured by using an in-mold injection molding process or a 3D printing process.

Exemplarily, the insulating body 31 is made of silica gel or plastic.

In some embodiments, the conductive structure 32 is a metal conductor. The metal conductor exhibits a good effect of dissipating static charges. Exemplarily, the metal conductor is made of gold, silver, copper, aluminum, zinc, iron, or nickel.

As shown in FIG. 3, the display panel 10 includes a back film layer 11 and a display layer 12. The display layer 12 includes a light-emitting surface and a backlight surface opposite to each other, the light-emitting surface of the display layer 12 and the light-emitting surface of the display panel 10 are oriented in the same direction, the backlight surface of the display layer 12 and the backlight surface of the display panel 10 are oriented in the same direction, and the back film layer 11 is disposed on the backlight surface of the display layer 12. The back film layer 11 serves the function of providing support, and the display layer 12 is configured for light emission and display.

In some embodiments, the display panel 10 is an organic light-emitting diode (OLED) display panel, a quantum dot light-emitting diode (QLED) display panel, a micro light-emitting diode (Micro LED) display panel, or the like.

In some embodiments, taking the OLED display panel as an example, the display layer 12 includes a base substrate, a drive circuit layer, and a light-emitting functional layer that are sequentially stacked.

In some embodiments, the base substrate is a flexible substrate or a non-flexible substrate, and the non-flexible substrate is a glass substrate, a plastic substrate, or the like. In some embodiments, the base substrate is a single-layer structure or a multi-layer structure.

In some embodiments, the drive circuit layer includes multiple pixel drive circuits, and the multiple pixel drive circuits are sequentially stacked on the base substrate. Each pixel drive circuit includes at least one thin-film transistor (TFT), a light-shielding structure corresponding to the at least one TFT, and the like.

The light-emitting functional layer includes multiple light-emitting units, and each light-emitting unit is connected to a corresponding pixel drive circuit. Exemplarily, each light-emitting unit includes an anode, a light-emitting layer, and a cathode.

In some embodiments, the light-emitting functional layer includes an anode layer, a pixel definition layer, a light-emitting layer, a cathode layer, and multiple pixel units. The pixel definition layer includes multiple openings, and each opening is provided with one light-emitting unit. At least part of the anode of the light-emitting unit is disposed in the opening, and the light-emitting layer of the light-emitting unit is disposed in the opening. The cathodes of the light-emitting units are connected to each other to form the cathode layer. Exemplarily, the anode layer is a metal layer, such as Cu, Ag, or Ti. Exemplarily, the light-emitting layer includes an electron injection layer (EIL), an electron transport layer (ETL), a hole block layer (HBL), a light-emitting material layer, a hole transport layer (HTL), a hole injection layer (HIL), and an electron blocking layer (EBL) that are sequentially stacked. Exemplarily, the cathode layer is a transparent conductive layer, such as an indium tin oxide (ITO) layer or an indium zinc oxide (IZO) layer.

In some embodiments, the display layer 12 is bonded to the cover plate 20 by using an adhesive layer 50. The adhesive layer 50 allows the display layer 12 to be more firmly bonded to the cover plate 20. Exemplarily, the adhesive layer 50 is an optically clear adhesive (OCA) layer or a thermal-melt optical clear adhesive (TOCA) layer.

As shown in FIG. 3, the display device further includes a light-shielding structure 40. The light-shielding structure 40 is disposed on the surface of the cover plate 20 proximal to the display panel 10 and disposed at the edge of the cover plate 20, and the light-shielding structure 40 is connected to the conductive structure 32. In this way, the light-shielding structure 40 shields the edge portion of the display device, which prevents light leakage at the edge of the display device, thereby improving the display effect of the display device. The static charges generated on the cover plate 20 are transmitted from the edge of the cover plate 20 to the conductive structure 32 through the light-shielding structure 40, thus facilitating the dissipation of the static charges.

In some embodiments, the light-shielding structure 40 is light-shielding ink. Alternatively, the light-shielding structure 40 may also be made of other light-shielding materials, which are not limited in the present disclosure.

As shown in FIG. 3, the display device further includes a heat dissipation layer 60, and the heat dissipation layer 60 is disposed on the backlight surface of the display panel 10. The heat dissipation layer 60 promotes the heat dissipation of the display panel 10.

In some embodiments, the heat dissipation layer 60 is a super clean foam (SCF) layer or a composite film layer. The SCF layer provides the buffering, light shielding, and heat dissipation effects for the display panel 10. The SCF layer includes a copper foil, a foam layer, and a bonding layer sequentially disposed from bottom to top in the thickness direction of the display device. That is, the copper foil is disposed on the surface of the SCF layer that is oriented in the same direction as the backlight surface of the display panel 10. The copper foil serves the functions of electric conduction, heat dissipation, and shielding, the foam layer plays a buffering role, and the bonding layer is the EMBO embossing adhesive that possesses the functions of adhesion and expelling air during the bonding process.

In some embodiments, the display device further includes a metal support layer, and the metal support layer is disposed on the backlight surface of the display panel 10. The metal support layer provides a certain degree of support and plays a certain support role for the display panel 10 to ensure the form of the display device, and the metal support layer is conductive.

Exemplarily, the metal support layer is a steel use stainless (SUS) layer, and the SUS layer is disposed on the backlight surface of the display panel 10. The SUS layer exhibits good conductivity and is connected to a third connection structure of the conductive structure 32. This is beneficial for dissipating the static charges.

In some embodiments, the grounding member includes at least one of the copper foil in the SCF layer, the metal support layer, or an integral middle frame. In FIG. 3, the heat dissipation layer 60 is an SCF layer, and the grounding member is a copper foil in the SCF layer. Alternatively, the grounding member may be an integral middle frame, or may include both the copper foil in the SCF layer and the integral middle frame, or may include only the metal support layer, or the like. The metal support layer and the integral middle frame ensure the stability and reliability of the display device. In addition, the copper foil in the SCF layer, the metal support layer, or the integral middle frame transmits and grounds the static charges generated on the cover plate 20, thereby facilitating the dissipation of static charges. The integral middle frame refers to a frame structure or a component thereof (usually disposed between the front panel and the rear cover plate to support other structures) provided for fixing various components of the display device or a product including the display device. The integral middle frame is, for example, a middle frame of a mobile phone device, and is made of, for example, a conductive material (such as metal or alloy).

As shown in FIG. 3, the conductive structure 32 includes at least one connector, and the connector includes a first connection structure 321 and a second connection structure 322. An end of the second connection structure 322 is connected to the first connection structure 321, and a side surface of the first connection structure 321 is attached to the edge of the cover plate 20. There is a gap between the second connection structure 322 and the sidewall of the display panel 10.

In FIG. 3, the first connection structure 321 is of a strip-shaped structure, and the length direction of the first connection structure 321 is parallel to the surface of the cover plate 20. That is, on the schematic structural diagram of the display device shown as FIG. 3, the planar view of the connector is T-shaped or inverted L-shaped. Since the length direction of the first connection structure 321 is parallel to the surface of the cover plate 20, the contact area between the conductive structure 32 and the cover plate 20, thereby further accelerating the diffusion of the static charges. Alternatively, the first connection structure 321 may also be of other plate-shaped structures, such as a circular plate, an elliptical plate, or a rectangular plate, and the plate surface of the plate-shaped structure is attached to the edge of the cover plate 20, which is not limited in the present disclosure.

In some embodiments, the conductive structure 32 further includes a third connection structure 323. The third connection structure 323 is connected to an end of the second connection structure 322 distal to the first connection structure 321, and is connected to the grounding member.

As shown in FIG. 3, the grounding member is attached to the backlight surface of the display panel 10, and a side surface of the third connection structure 323 is attached to the surface of the grounding member distal to the display panel 10. The static charges generated on the cover plate 20 are transmitted from the edge of the cover plate 20 to the conductive structure 32 and then transmitted to the grounding member through the third connection structure 323, which is beneficial for dissipating the static charges, thereby reducing problems such as edge greening.

In FIG. 3, the third connection structure 323 is connected to the grounding member on the backlight surface of the display panel 10, and the third connection structure 323 is of a strip-shaped structure, and its length direction is parallel to the surface of the heat dissipation layer 60. In this way, the contact area between the conductive structure 32 and the grounding member can be increased, thereby further accelerating the diffusion of the static charges. Alternatively, the third connection structure 323 may also be of other plate-shaped structures, such as a circular plate, an elliptical plate, or a rectangular plate, and the plate surface of the plate-shaped structure is attached to the surface of the grounding member distal to the display panel 10, which is not limited in the present disclosure.

In some embodiments, the third connection structure 323 is a snap-fit, a bolt, or a nut. These structures can ensure the reliable connection between the conductive structure 32 and the integral middle frame, and the static charges generated on the cover plate 20 can be transmitted from the edge of the cover plate 20 to the conductive structure 32 and then transmitted through the third connection structure 323 to the integral middle frame for grounding, which is beneficial for dissipating the static charges, thereby reducing problems such as edge greening.

FIG. 4 is a schematic structural diagram of another display device according to some embodiments of the present disclosure. The display device shown in FIG. 4 differs from the display device shown in FIG. 3 in that the third connection structure 323 is different. In FIG. 4, an end of the second connection structure 322 distal to the first connection structure 321 protrudes from the surface of the insulating body 31 that is oriented in the same direction as the backlight surface of the display panel 10. The third connection structure 323 is a snap-fit. The snap-fit is of a strip-shaped structure, and its length direction is parallel to the surface of the heat dissipation layer 60. The integral middle frame includes a corresponding snap-fit, and the integral middle frame is reliably connected to the third connection structure 323 through the corresponding snap-fit.

FIG. 5 is a schematic structural diagram of yet another display device according to some embodiments of the present disclosure. The display device shown in FIG. 5 differs from the display devices in FIG. 3 and FIG. 4 in that the third connection structure 323 is different. The third connection structure 323 in FIG. 5 is a nut. The nut is embedded in the insulating body 31 and flush with the surface of the insulating body 31 that is oriented in the same direction as the backlight surface of the display panel 10. In this case, the integral middle frame includes a corresponding connecting bolt, and the integral middle frame is connected to the third connection structure 323 through the corresponding connecting bolt.

The third connection structure 323 in FIG. 4 and FIG. 5 facilitates the connection between the conductive structure 32 and the integral middle frame, thereby facilitating the dissipation of static charges.

In some embodiments, the conductive structure 32 includes multiple connectors, and the multiple connectors are arranged spaced apart from each other around the display panel 10. Exemplarily, the conductive structure includes 12 connectors. The display panel 10 has two long sides and two short sides; four connectors are spaced equally along each long side of the display panel 10, and two connectors are spaced equally along each short side of the display panel 10, such that the 12 connectors are evenly arranged around the display panel 10. Alternatively, the connectors may also be arranged in other quantities or with other spacing configurations, which is not limited in the present disclosure.

In other embodiments, the conductive structure 32 in FIG. 3 to FIG. 5 includes only one connector. The connector is of an annular structure surrounding the display panel 10, and the connector is embedded in the insulating body 31, which also facilitates the diffusion of the static charges and reduces problems such as edge greening caused by the accumulation of the static charges at the edge of the cover plate 20.

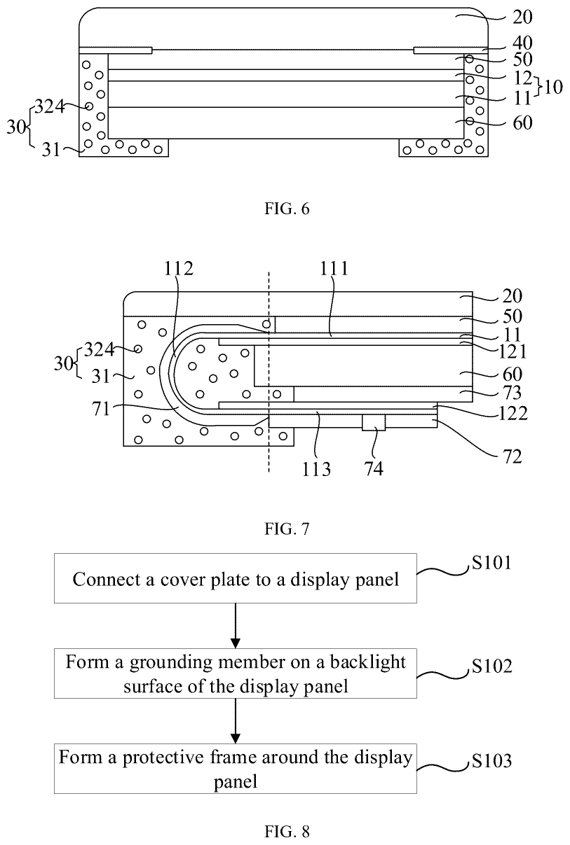

FIG. 6 is a schematic structural diagram of yet another display device according to some embodiments of the present disclosure. The display device shown in FIG. 6 differs from the display devices in FIG. 3 to FIG. 5 in that the conductive structure 32 is different. As shown in FIG. 6, the conductive structure 32 of the display device includes multiple conductive particles 324, and the multiple conductive particles 324 are evenly distributed in the insulating body 31. In the schematic structural diagram of the display device shown in FIG. 6, the insulating body 31 is of an annular structure, surrounds the display panel 10, and covers the edge of the surface of the heat dissipation layer 60 that is oriented in the same direction as the backlight surface of the display panel 10, and the insulating body 31 is connected to the edge of the cover plate 20. In this way, the protective frame 30 includes multiple conductive particles, and the multiple conductive particles are evenly distributed in the insulating body 31, such that the impedance of the protective frame is reduced, and the dissipation of the static charges is accelerated.

In some embodiments, the conductive particles 324 include at least one of a metal particle, a graphene particle, or a carbon nanotube particle. These particles exhibit a good effect of dissipating the static charges. The metal particle includes one or more of gold, silver, copper, aluminum, zinc, iron, or nickel particles. Exemplarily, the conductive particles 324 are silver particles and copper particles.

FIG. 7 is a schematic structural diagram of yet another display device according to some embodiments of the present disclosure. As shown in FIG. 7, the display device includes a display layer 11, a first back film layer 121, a second back film layer 122, a cover plate 20, a protective frame 30, an adhesive layer 50, a heat dissipation layer 60, a micro coating layer (MCL) adhesive 71, a flexible printed circuit (FPC) 72, a pressure sensitive adhesive (PSA) layer 73, and an integrated circuit (IC) chip 74. The display layer 11 is flexible, the heat dissipation layer 60 is an SCF layer, and the adhesive layer 50 is a TOCA layer.

In FIG. 7, the display layer 11 is bent in a specific direction to make the light-emitting surface convex, and the display layer 11 is divided into three different areas based on a dashed line, that is, a display part 111, a bending part 112, and a binding part 113. The upper surface of the display part 111 in the figure is the light-emitting surface. In FIG. 7, the FPC 72, the binding part 113 of the display layer 11, the second back film layer 122, the PSA layer 73, the heat dissipation layer 60, the first back film layer 121, and the display part 111 of the display layer 11 are sequentially stacked from bottom to top, and the display part 111 of the display layer 11 is connected to the cover plate 20 through the adhesive layer 50. The protective frame 30 is disposed around the flexible printed circuit 72, the display layer 11, the second back film layer 122, the PSA layer 73, the heat dissipation layer 60, the first back film layer 121, and the adhesive layer 50, and is connected to the edge of the cover plate 20. The protective frame includes an insulating body 31 and multiple conductive particles 324, and the multiple conductive particles 324 are evenly distributed in the insulating body 31. The MCL adhesive 71 is disposed in the insulating body 31 and on the light-emitting surface of the bending part 112 of the display layer 11, and the IC chip 74 is disposed in the middle of the FPC 72 and on the surface, distal to the second back film layer 122, of the binding part 113 of the display layer 11. Since the multiple conductive particles are evenly distributed in the insulating body 31, the impedance of the protective frame is reduced, and the dissipation of static charges is accelerated.

FIG. 8 is a flowchart of a method for manufacturing a display device according to some embodiments of the present disclosure. As shown in FIG. 8, the method includes the following steps.

In S101, a cover plate is connected to a display panel.

The cover plate is disposed on a light-emitting surface of the display panel.

In S102, a grounding member is formed on a backlight surface of the display panel.

In S103, a protective frame is formed around the display panel.

The protective frame is connected to an edge of the cover plate, the protective frame includes an insulating body and a conductive structure, the conductive structure is embedded in the insulating body, and the conductive structure is connected to the edge of the cover plate and electrically connected to the grounding member.

In the embodiments of the present disclosure, the grounding member is disposed on the backlight surface of the display panel, the protective frame is disposed around the display panel and connected to the edge of the cover plate, the protective frame includes an insulating body and a conductive structure embedded in the insulating body, and the conductive structure is connected to the edge of the cover plate and electrically connected to the grounding member. In the case that static charges are generated on the cover plate, the conductive structure in the protective frame can transmit the static charges to the grounding member for grounding, which facilitates the diffusion of the static charges and reduces problems such as edge greening caused by the accumulation of the static charges at the edge of the cover plate, thereby improving the yield of display devices.

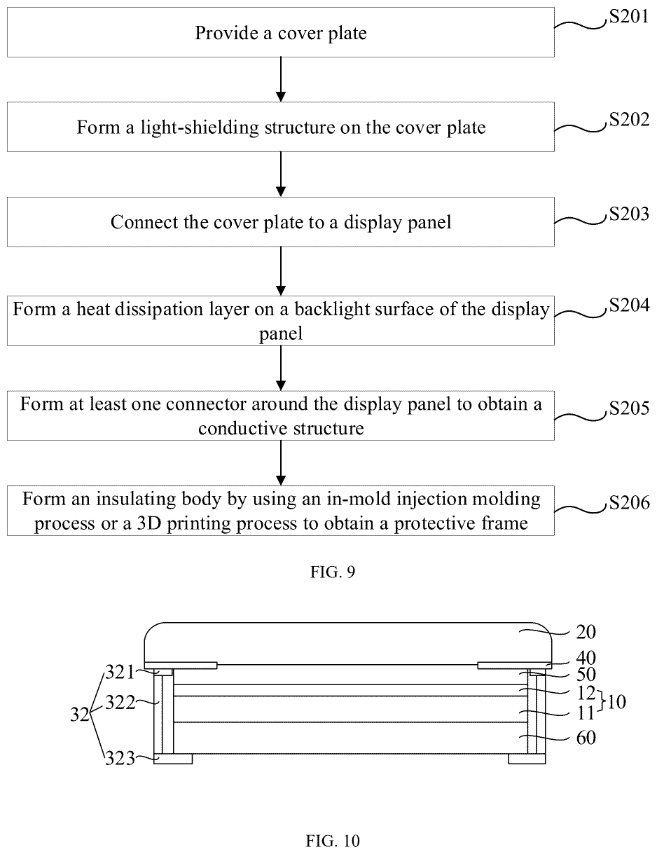

FIG. 9 is a flowchart of another method for manufacturing a display device according to some embodiments of the present disclosure. As shown in FIG. 9, the method includes the following steps.

In S201, a cover plate is provided.

In S202, a light-shielding structure is formed on the cover plate.

In S203, the cover plate is connected to a display panel.

FIG. 10 is a schematic structural diagram of a display device during manufacturing according to some embodiments of the present disclosure. As shown in FIG. 10, a light-shielding structure 40 is disposed on the surface of a cover plate 20 proximal to a display panel 10, and is disposed at the edge of the cover plate 20.

In some embodiments, reference is made to embodiments related to FIG. 3 to FIG. 5 for the structure and material of the display panel 10, and detailed descriptions are omitted herein.

In S204, a heat dissipation layer is formed on a backlight surface of the display panel.

As shown in FIG. 10, the heat dissipation layer 60 is disposed on the backlight surface of the display panel 10.

In some embodiments, the heat dissipation layer 60 is an SCF layer. The surface of the SCF layer that is oriented in the same direction as the backlight surface of the display panel 10 is a copper foil, and the grounding member is the copper foil in the SCF layer.

In S205, at least one connector is formed around the display panel to obtain a conductive structure.

The connector includes a first connection structure and a second connection structure. An end of the second connection structure is connected to the first connection structure, and a side surface of the first connection structure is attached to the edge of the cover plate.

In some embodiments, after at least one connector is formed, the step further includes forming a third connection structure. The third connection structure is connected to an end of the second connection structure distal to the first connection structure, and is connected to the grounding member.

In some embodiments, reference is made to embodiments related to FIG. 3 to FIG. 5 for the shapes and positions of the connector and the third connection structure, and detailed descriptions are omitted herein.

In S206, an insulating body is formed by using an in-mold injection molding process or a 3D printing process to obtain a protective frame.

FIG. 11 is a schematic structural diagram of another display device during manufacturing according to some embodiments of the present disclosure. As shown in FIG. 11, in the case that the in-mold injection molding process is adopted, the S206 is mold clamping. That is, an upper mold 81 and a lower mold 82 are first clamped together, and the gap between the molds is the space required for the insulating body; then, the material is injected into the mold, and after the material sets, demolding is performed to form the insulating body, thus obtaining the protective frame. In addition, the conductive structure 32 is embedded in the insulating body.

Through the above S201 to S206, the display devices as shown in FIG. 3, FIG. 4, or FIG. 5 are finally obtained.

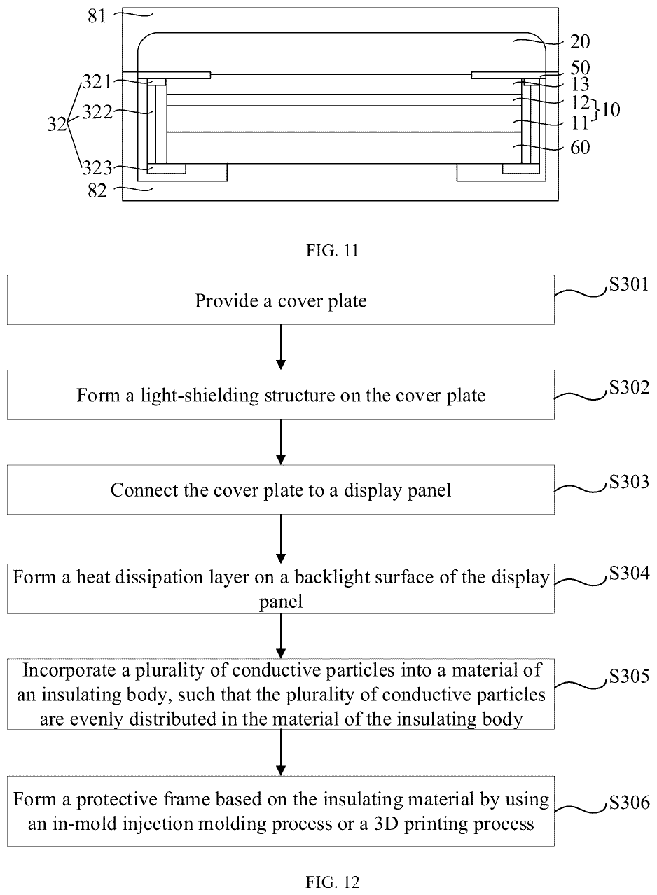

FIG. 12 is a flowchart of yet another method for manufacturing a display device according to some embodiments of the present disclosure. As shown in FIG. 12, the method includes the following steps.

In S301, a cover plate is provided.

In S302, a light-shielding structure is formed on the cover plate.

In S303, the cover plate is connected to a display panel.

The light-shielding structure is disposed on the surface of the cover plate proximal to the display panel, and is disposed at the edge of the cover plate.

In some embodiments, reference is made to embodiments related to FIG. 6 for the structure and material of the display panel, and detailed descriptions are omitted herein.

In S304, a heat dissipation layer is formed on a backlight surface of the display panel.

In some embodiments, the heat dissipation layer is an SCF layer. The surface of the SCF layer that is oriented in the same direction as the backlight surface of the display panel is a copper foil, and the grounding member is the copper foil in the SCF layer.

In S305, multiple conductive particles are incorporated into an insulating material, such that the multiple conductive particles are evenly distributed in the insulating material.

In some embodiments, the conductive particles include at least one of a metal particle, a graphene particle, or a carbon nanotube particle.

In S306, a protective frame is formed based on the insulating material by using an in-mold injection molding process or a 3D printing process.

Through the above S301 to S306, the display devices as shown in FIG. 6 are finally obtained.

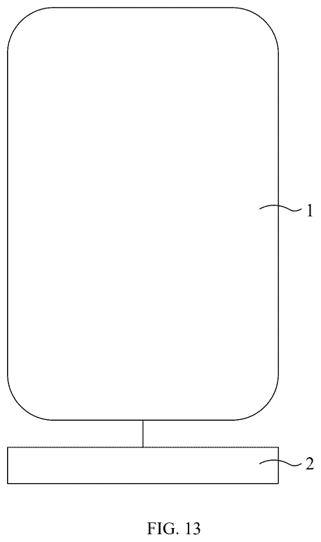

FIG. 13 is a schematic structural diagram of a display apparatus according to some embodiments of the present disclosure. As shown in FIG. 13, the display apparatus includes the display device 1 described above and a power supply 2, and the power supply 2 is electrically connected to the display device 1.

In some embodiments, the display apparatus is any product or component having a display function, such as a mobile phone, a tablet computer, or a display.

The above description does not limit the present disclosure in any way. Although the present disclosure has been disclosed as above through the embodiments, they are not intended to limit the present disclosure. Those skilled in the art are able to make some changes or modifications to the above-disclosed technical contents to give equivalent embodiments of equivalent changes without departing from the scope of the present disclosure. However, any simple alterations, equivalent changes, and modifications made, without departing from the contents of the technical solutions of the present disclosure, on the above embodiments based on the technical essence of the present disclosure shall fall within the scope of the technical solutions of the present disclosure.

1. A display device, comprising:
a display panel;
a cover plate disposed on a light-emitting surface of the display panel;
a grounding member disposed on a backlight surface of the display panel; and
a protective frame disposed around the display panel and connected to an edge of the cover plate, wherein the protective frame comprises an insulating body and a conductive structure embedded in the insulating body, the conductive structure being connected to the edge of the cover plate and connected to the grounding member.

2. The display device according to claim 1, wherein the conductive structure comprises at least one connector, the connector comprises a first connection structure and a second connection structure, an end of the second connection structure is connected to the first connection structure, and a side surface of the first connection structure is attached to the edge of the cover plate.

3. The display device according to claim 2, wherein the conductive structure further comprises a third connection structure, and the third connection structure is connected to an end of the second connection structure distal to the first connection structure, and is connected to the grounding member.

4. The display device according to claim 3, wherein the grounding member is attached to the backlight surface of the display panel, and a side surface of the third connection structure is attached to a surface of the grounding member distal to the display panel.

5. The display device according to claim 3, wherein the third connection structure is a snap-fit, a bolt, or a nut.

6. The display device according to claim 2, wherein the conductive structure comprises a plurality of connectors, and the plurality of connectors are arranged spaced apart from each other around the display panel.

7. The display device according to claim 1, wherein the conductive structure contains a plurality of conductive particles, and the plurality of conductive particles are evenly distributed in the insulating body.

8. The display device according to claim 1, wherein the grounding member comprises at least one of a metal support layer, an integral middle frame, or a copper foil in a super clean foam layer.

9. The display device according to claim 1, wherein the display panel comprises a back film layer and a display layer, the display layer comprises a light-emitting surface and a backlight surface opposite to each other, the light-emitting surface of the display layer faces the same direction as the light-emitting surface of the display panel, the backlight surface of the display layer faces the same direction as the backlight surface of the display panel, and the back film layer is disposed on the backlight surface of the display layer.

10. The display device according to claim 1, further comprising a light-shielding structure, wherein the light-shielding structure is disposed on a surface of the cover plate proximal to the display panel and at the edge of the cover plate, and the light-shielding structure is conductive and connected to the conductive structure.

11. The display device according to claim 1, wherein the insulating body is manufactured by using an in-mold injection molding process or a 3D printing process.

12. A method for manufacturing a display device, comprising:
connecting a cover plate to a display panel, wherein the cover plate is disposed on a light-emitting surface of the display panel;
forming a grounding member on a backlight surface of the display panel; and
forming a protective frame around the display panel, wherein the protective frame is connected to an edge of the cover plate, the protective frame comprises an insulating body and a conductive structure embedded in the insulating body, and the conductive structure is connected to the edge of the cover plate and connected to the grounding member.

13. The method according to claim 12, wherein forming the protective frame comprises:
forming at least one connector around the display panel, wherein the connector comprises a first connection structure and a second connection structure, an end of the second connection structure is connected to the first connection structure, and a side surface of the first connection structure is attached to the edge of the cover plate; and
forming the insulating body by using an in-mold injection molding process or a 3D printing process to obtain the protective frame.

14. The method according to claim 12, wherein forming the protective frame comprises:
incorporating a plurality of conductive particles into an insulating material, such that the plurality of conductive particles are evenly distributed in the insulating material; and
forming the protective frame based on the insulating material by using an in-mold injection molding process or a 3D printing process.

15. A display apparatus, comprising a display device and a power supply, wherein the display device is connected to the power supply; the display device comprises:
a display panel;
a cover plate disposed on a light-emitting surface of the display panel;
a grounding member disposed on a backlight surface of the display panel; and
a protective frame disposed around the display panel and connected to an edge of the cover plate, wherein the protective frame comprises an insulating body and a conductive structure embedded in the insulating body, the conductive structure being connected to the edge of the cover plate and connected to the grounding member.

16. The display apparatus according to claim 15, wherein the conductive structure comprises at least one connector, the connector comprises a first connection structure and a second connection structure, an end of the second connection structure is connected to the first connection structure, and a side surface of the first connection structure is attached to the edge of the cover plate.

17. The display apparatus according to claim 16, wherein the conductive structure further comprises a third connection structure, and the third connection structure is connected to an end of the second connection structure distal to the first connection structure, and is connected to the grounding member.

18. The display apparatus according to claim 17, wherein the grounding member is attached to the backlight surface of the display panel, and a side surface of the third connection structure is attached to a surface of the grounding member distal to the display panel.

19. The display apparatus according to claim 17, wherein the third connection structure is a snap-fit, a bolt, or a nut.

20. The display apparatus according to claim 16, wherein the conductive structure comprises a plurality of connectors, and the plurality of connectors are arranged spaced apart from each other around the display panel.
